(19) United States
(12) Patent Application Publication
(10) Pub. No.: US 2026/0045459 A1
(43) Pub. Date: Feb. 12, 2026

(54) IN SITU SIDEWALL CLEANING DURING PLASMA ETCH WITH METAL-CONTAINING MASK

(71) Applicant: Tokyo Electron Limited, Tokyo (JP)

(72) Inventors: Michael Ramsey, Albany, NY (US); Joshua Baillargeon, Albany, NY (US); Alec Dorfner, Albany, NY (US); Minjoon Park, Albany, NY (US)

(21) Appl. No.: 18/797,786

(22) Filed: Aug. 8, 2024

(51) Int. Cl. H01J 37/32

(52) U.S. Cl. CPC H01J 37/32862; H01J 37/32449; H01J 2237/334

(57) ABSTRACT

A method of plasma etching includes cyclically performing the following steps: etching an underlying material, such as a dielectric material, to extend recesses into the underlying material through openings in a metal-containing mask layer, such as a tungsten silicide, using plasma excited from an etchant gas including at least one hydrofluorocarbon etchant species, such as trifluoromethane; and etching residual material from sidewalls of the recesses using plasma excited from a pure oxygen gas, such as pure diatomic oxygen gas, the residual material being deposited while etching the underlying material. All species of the etchant gas include no more than one carbon and include an element other than fluorine and carbon.

### TECHNICAL FIELD

The present invention relates generally to etching processes, and, in particular embodiments, to systems and methods for plasma etching an underlying material through a metal-containing mask.

### BACKGROUND

Microelectronic device fabrication typically involves a series of manufacturing techniques that include formation, patterning, and removal of a number of layers of material on a substrate. Etch masks may be formed (e.g., deposited, grown) to protect regions of the substrate and allow for pattern transfer via etching. Wet or dry etching processes may be used, with plasma etching processes being an example of a dry etching process. Etching processes are used in a variety of semiconductor processing areas such as in memory manufacture. One category of etching processes is high aspect ratio (HAR) etching, which includes processes such as high aspect ratio contact (HARC) etches for contact formation. Obtaining a high aspect ratio during etching is important for a variety of semiconductor processes such as during NAND formation (e.g., 3D-NAND), NOR gate formation, through-silicon via (TSV) formation, deep trench capacitors, and others.

During plasma etching processes (such as HAR etching processes), residual material (e.g., polymer buildup) can accumulate in openings of the mask, on feature sidewalls, and at the bottom of etched structures. While some material buildup can be beneficial for achieving anisotropic etching by passivating sidewalls, excessive buildup can lead to several issues, including reduced etch rates, feature closure, and residue-related defects. Strategies to control material buildup typically focus on optimizing gas mixtures to balance deposition and removal during the plasma etching process. However, as device geometries become more complex and critical dimensions continue to shrink, etch gas mixture optimization alone is not suitable to manage residual material accumulation without compromising etch profile, etch selectivity, or throughput.

### SUMMARY

In accordance with an embodiment of the invention, a method of plasma etching includes cyclically performing the following steps: etching an underlying material to extend recesses into the underlying material through openings in a metal-containing mask layer using plasma excited from an etchant gas including at least one hydrofluorocarbon etchant species; and etching residual material from sidewalls of the recesses using plasma excited from a pure oxygen gas, the residual material being deposited while etching the underlying material. All species of the etchant gas include no more than one carbon and include an element other than fluorine and carbon.

In accordance with another embodiment of the invention, a method of HAR etching includes cyclically performing the following steps: performing a lean etch step that includes flowing an etchant gas into a plasma etching chamber and exciting plasma from the etchant gas to extend recesses into an underlying material through openings in a metal-containing mask layer by etching the underlying material; and performing a sidewall cleaning step that includes flowing a pure O₂ gas into the plasma etching chamber, and exciting plasma from the pure O₂ gas to etch residual material deposited during the lean etch step from sidewalls of the recesses. The etchant gas includes at least one hydrofluorocarbon etchant species and a carbon-free fluorine-containing species. All species of the etchant gas include no more than one carbon and include an element other than fluorine and carbon.

In accordance with still another embodiment of the invention, a plasma etching system includes a plasma etching chamber; a substrate holder disposed in the plasma etching chamber, an etchant source fluidically coupled to the plasma etching chamber, an oxygen source fluidically coupled to the plasma etching chamber, a source power supply configured to couple source power to gases in the plasma etching chamber to excite plasma therein, and a controller operationally coupled to the etchant source, the oxygen source, and the source power supply. The substrate holder is configured to support a substrate including a metal-containing mask layer including openings exposing an underlying material. The etchant source is configured to flow one or more gases including at least one hydrofluorocarbon etchant species into the plasma etching chamber. All species of the one or more gases include no more than one carbon and include an element other than fluorine and carbon. The oxygen source is configured to flow a pure oxygen gas into the plasma etching chamber.

The controller includes a processor and a non-transitory computer-readable medium storing a program including instructions that, when executed by the processor, perform a method of plasma etching by cyclically performing a lean etch step that includes flowing the one or more gases into the plasma etching chamber and exciting plasma from the one or more gases to extend recesses into the underlying material by etching the underlying material, and performing a sidewall cleaning step that includes flowing the pure oxygen gas into the plasma etching chamber and exciting plasma from the pure oxygen gas to etch residual material deposited during the lean etch step from sidewalls of the recesses.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 schematically illustrates an example etching process that includes a lean etch step followed by a sidewall cleaning step where the lean etch step etches an underlying material through a metal-containing mask and the sidewall cleaning step etches residual material deposited during the lean etch step from feature sidewalls using plasma excited from a pure oxygen gas in accordance with embodiments of the invention;

FIG. 2 schematically illustrates an example etching process that includes a lean etch step followed by a sidewall cleaning step where two cycles of the etching process are shown in accordance with embodiments of the invention;

FIG. 3 schematically illustrates an example etching process that includes a lean etch step followed by a sidewall cleaning step, where the etchant gas is a mixture of etchant species in accordance with embodiments of the invention;

FIG. 4 schematically illustrates an example etching process that includes a lean etch step followed by a sidewall cleaning step, where the etchant gas has two carbon-containing etchant species, a carbon-free fluorine-containing species, and a balancing species in accordance with embodiments of the invention;

FIG. 5 illustrates a timing diagram qualitatively showing flowrates of an etchant gas and a pure oxygen gas, chamber pressure, source power, and bias power during both a lean etch step and a sidewall cleaning step of an example etching process in accordance with embodiments of the invention;

FIG. 6 schematically illustrates an example plasma etching system usable to perform etching processes that include a lean etch step followed by a sidewall cleaning step in accordance with embodiments of the invention; and

FIG. 7 illustrates a flowchart of a method of plasma etching that use etching processes including a lean etch step followed by a sidewall cleaning step in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

During plasma etching processes, a target material (e.g., an underlying material exposed through openings of a mask layer) interacts with plasma species (and potentially also with non-plasma species) to remove material. Although plasma etching processes are designed to be highly selective, residual material, such as polymers, can accumulate (i.e., be deposited) during many plasma etching processes. Some degree of material buildup is desirable in certain circumstances, such as to provide passivation to sidewalls of etched recesses in the target material or to increase etch selectivity if material preferentially accumulates at top surfaces of mask features. However, excessive residual material on surfaces of the mask layer (e.g., at the openings) and the target material (e.g., on sidewalls) can cause adverse effects.

Material accumulation during the etching process, such as fluorocarbon polymer buildup during plasma etching processes that use etchant gases containing fluorine and carbon, the counteracting effects of etching and deposition are often balanced of the course of an entire etch by optimizing gas composition as well as other process parameters, such as relative gas flowrates, chamber pressure, source and bias power, etc. Oxygen plasma can be effective at removing residual material, such as polymer buildup, but is also effective at removing other carbon-containing materials. Carbon-containing masks like amorphous carbon layer (ACL) masks and spin-on carbon (SoC) masks are frequently used as etch masks for various materials, such as when etching dielectric materials. Oxygen plasma is not feasible for removing residual material during a plasma etching process that uses a carbon-containing mask because the carbon-containing mask is also removed by the oxygen plasma causing an unworkable decrease in etch selectivity.

Metal-containing masks may be an alternative to carbon-containing masks for certain plasma etching processes. The selectivity of etching interactions with a target material (e.g., a dielectric material) relative to etching interactions with the metal-containing mask material may be much higher than for a carbon-containing mask (i.e., for the same etch conditions and target material, the metal-containing mask may be removed much slower than the carbon-containing mask). This may allow a much thinner metal-containing mask layer (e.g., on the order of hundreds of nanometers rather than the several microns that may be needed for a carbon-containing mask).

Because of the high selectivity of metal-containing masks, plasma etching processes that use metal-containing masks may be less reliant on material buildup to achieve desired process results, such as etch rate and etch selectivity. For this reason, etch gases may be used that produce less residual material (i.e., lean etch chemistry). However, the inventors have observed that even relatively lean etch conditions during certain plasma etching processes yield deposition that could benefit from balancing and/or removal (e.g., to avoid undesirable profile distortion, which may compromise device integrity). In particular, persistent in-feature deposition during the plasma etching process may result in notable deformation. For this reason, improved plasma etching processes that reduce in-feature deposition (e.g., material accumulation on sidewalls of the etched recesses) achieve a less distorted profile while maintaining etch rate may be desirable.

In accordance with embodiments herein described, the invention proposes a two-step plasma etching process that includes a lean etch step utilizing lean plasma chemistry to extend recesses into an underlying material (i.e., the target material) through openings in a metal-containing mask layer that is followed by a sidewall cleaning step with a pure oxygen plasma to etch residual material from sidewalls of the recesses. The sidewall cleaning step is advantageously able to be performed during the etching process. That is, the plasma etching process may be performed as a cycle where the two steps of the lean etch and the sidewall clean are repeated in situ (i.e., with the substrate containing the underlying material in place in the same plasma etching chamber) several times during the plasma etching process.

In various embodiments, the underlying material is etched using a plasma excited from an etchant gas that contains both fluorine and carbon. The etchant gas is configured to have lean etch chemistry (e.g., promoting fewer and smaller fluorocarbon species in the plasma). For example, all of the species of the etchant gas include no more than one carbon. In some embodiments, all species of the etchant gas include an element other than fluorine and carbon (e.g., hydrogen, nitrogen, oxygen, etc.). In various embodiments, species that do not include one or both carbon and fluorine are included in the etchant gas, such as a carbon-free fluorine containing species, a balancing species including oxygen, or both.

The pure oxygen gas includes only oxygen, but may be provided in various forms, or mixtures of forms. In various embodiments, the pure oxygen gas includes pure diatomic oxygen (O₂) gas, and only includes pure O₂ gas in one embodiment. The metal-containing mask layer may include any suitable material that has a metallic (i.e., metal or metalloid) component, such as tungsten (W), titanium (Ti), tin (Sn), silicon (Si), etc. The material of the metal-containing mask layer may be selected to be resistant to oxygen plasma (e.g., in comparison to carbon-containing masks that are often used in conventional etching processes). For example, this may enable the sidewall cleaning step to be used during the plasma etching process with a palatable decrease to etch selectivity and modification to the mask facet (in contrast to selectivity losses in other masks, such as carbon-containing masks, which would prevent completion of the full etch in some cases).

The embodiment plasma etching processes described herein, may have various advantages over conventional plasma etching processes. For example, the plasma etching processes may be beneficial for improving etch profile in HAR (high-aspect ratio) etching processes such as HARC etches using metal-containing mask materials, such as tungsten silicide (WSiₓ). The sidewall cleaning step may use pure oxygen plasma (e.g., pure O₂ plasma) and advantageously provide in-feature removal of residual material.

Even while reducing distortion in the etch profile, the etch rate may advantageously be maintained using lean etch chemistry and sidewall cleaning steps that have a short duration relative to the lean etch steps. In some cases, the improvements to etch profile may come at the expense of some mask selectivity and a more aggressive mask facet (which may pose a threat of top CD enlargement and tapering in some cases). However, the negative effects of including a sidewall cleaning step during the etching process may be relatively minor in comparison to drawbacks associated with conventional plasma etching processes, which may enable the use of metal-containing masks in more contexts. That is, combining a metal-containing mask with pure oxygen plasma conditions may advantageously yield a process window not conventionally available (e.g., when using a carbon-containing mask, such as an ACL mask).

Polymer buildup has been a problem for conventional plasma etching processes, such as those that use a carbon-containing mask (e.g., an ACL mask) and fluorocarbon etchant species (e.g., tetrafluoromethane (CF₄), higher order fluorocarbons, such as C₄F₆, C₄F₈, etc.). In these conventional processes, polymer buildup at openings of the mask is enhanced by the carbon-rich plasma chemistry (i.e., higher carbon to fluorine ratio and/or larger fluorocarbon species, which may be generated from polymerizing species, such as higher order fluorocarbons) as well as the presence of carbon in the mask itself. This causes adverse effects, such as reduced etch rate, closure of mask openings, and profile distortions, such as bowing.

As already discussed, since carbon-containing masks are etched by oxygen plasma, it is challenging to incorporate oxygen plasma into processes that have carbon-containing masks without compromising selectivity. Consequently, most conventional plasma etching processes with carbon-containing masks avoid oxygen plasma. However, flash steps utilizing oxygen plasma chemistry have been used to remove polymer at mask openings of carbon-containing masks in limited situations. In contrast to the embodiment plasma etching processes described in the present disclosure, conventional oxygen plasma flash steps used with carbon-containing masks are carefully tailored to target lateral polymer formations, such as the secondary facet, which are identified as the source of the problem in those contexts.

For example, in order to accomplish the desired result of removing polymer obstructing carbon-containing mask openings, the few conventional plasma etching processes that use a rich chemistry during the etch step to ensure that the vulnerable carbon-containing mask is protected by polymer and use an oxygen plasma flash step that uses bias power during the flash step target the lateral growth. In particular, conventional plasma etching processes with a carbon-containing mask that use a flash step may avoid removing sidewall polymer. These conventional plasma processes may also include heavy species (such as inert species) to increase the selectivity to the lateral formations through physical bombardment (in contrast to polymer removal using solely oxygen chemistry). Additionally, these conventional plasma processes may have more strict requirements on the duration of the flash step, the number of flash steps, and the total flash exposure time due to the vulnerability of the carbon-containing mask to oxygen chemistry.

Because the material of metal-containing masks may be selected to have very high selectivity compared to carbon-containing masks, conventional reasoning may be that an oxygen plasma cleaning step in situ during the plasma etching process would not be needed for metal-containing masks. For example, metal-containing masks may be much thinner than carbon-containing masks, for various reasons, such as the higher selectivity enabling thinner mask layers and also potentially due to increased stresses of metal-containing films on the underlying substrate. However, the inventors have observed that a cleaning step using oxygen plasma may be beneficial for etching accumulated residual material, such as polymer, off feature sidewalls. Specifically, and unexpectedly compared with conventional reasoning, including one or more oxygen plasma cleaning steps during the plasma etching process with a metal-containing mask may have benefits to etch profile such as reducing or eliminating all types of sidewall distortion, one example of which is sidewall bowing.

The plasma etching processes described herein improve upon conventional plasma etching processes by incorporating one or more features such as a metal-containing etch mask (e.g., tungsten-containing, such as WSiₓ), a dielectric etch target (e.g., oxide, nitride, ONON, etc.), lean etch chemistry during the etch step, pure oxygen plasma during the cleaning step, lower source power during the etch step, little or no bias power during the cleaning step, higher chamber pressure during the cleaning step, and purge-free gas switching, among others.

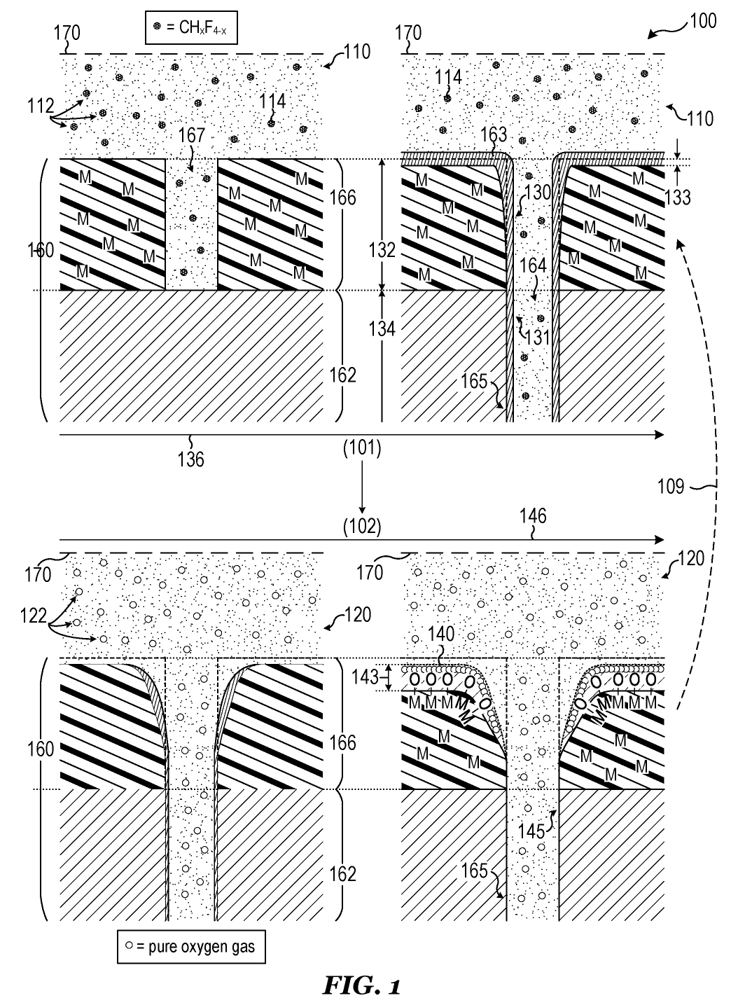

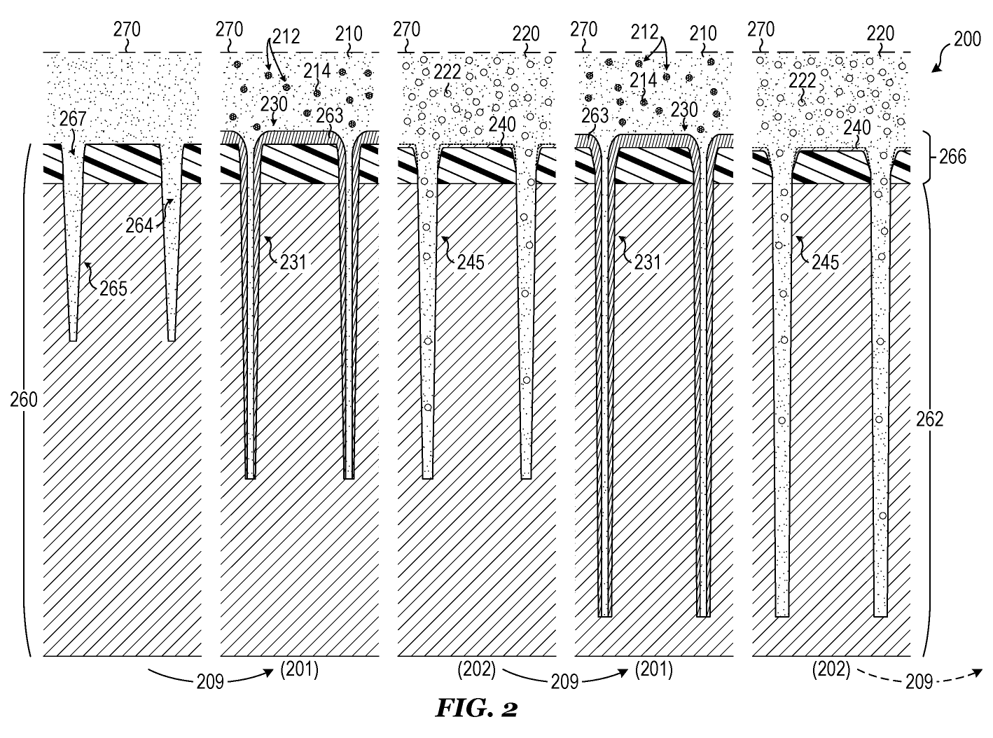

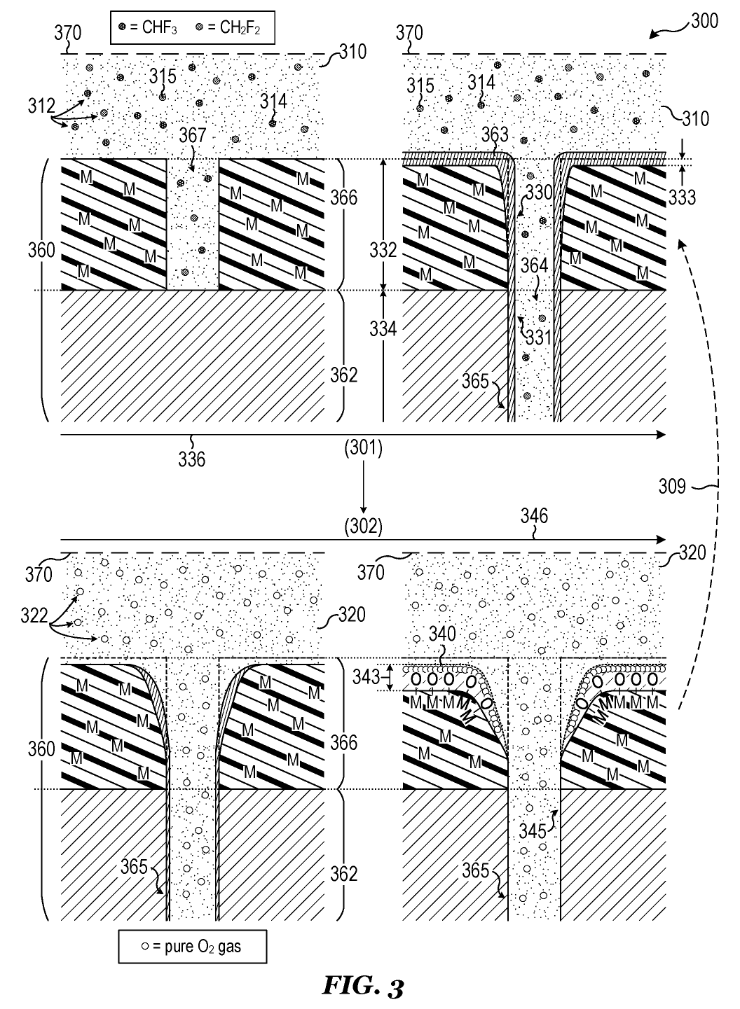

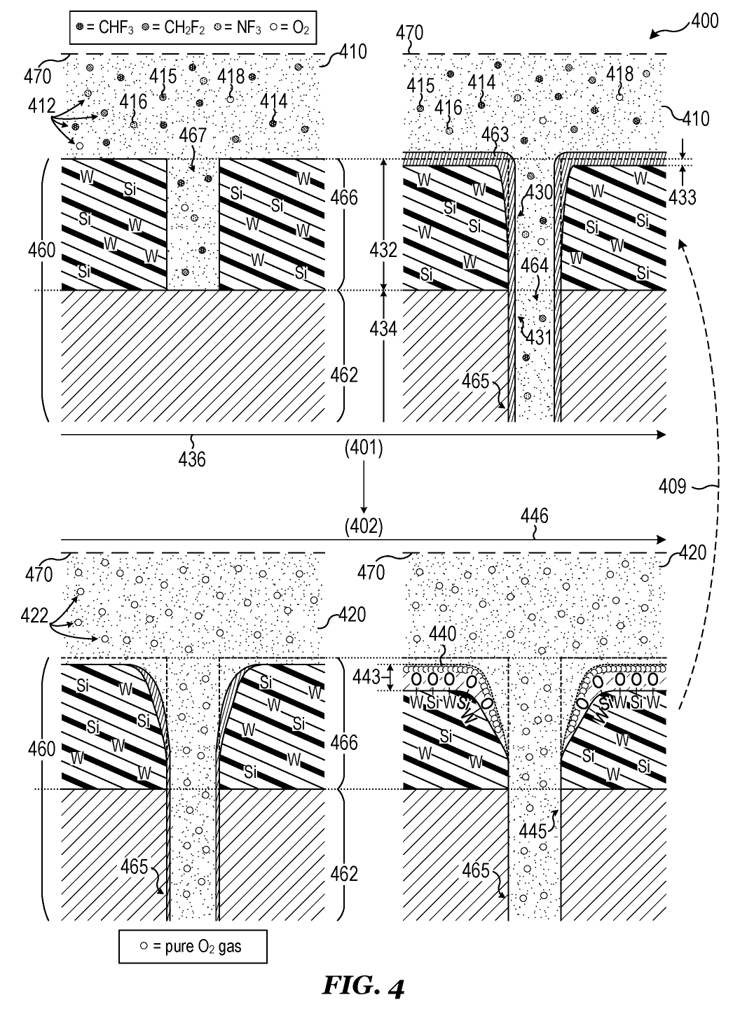

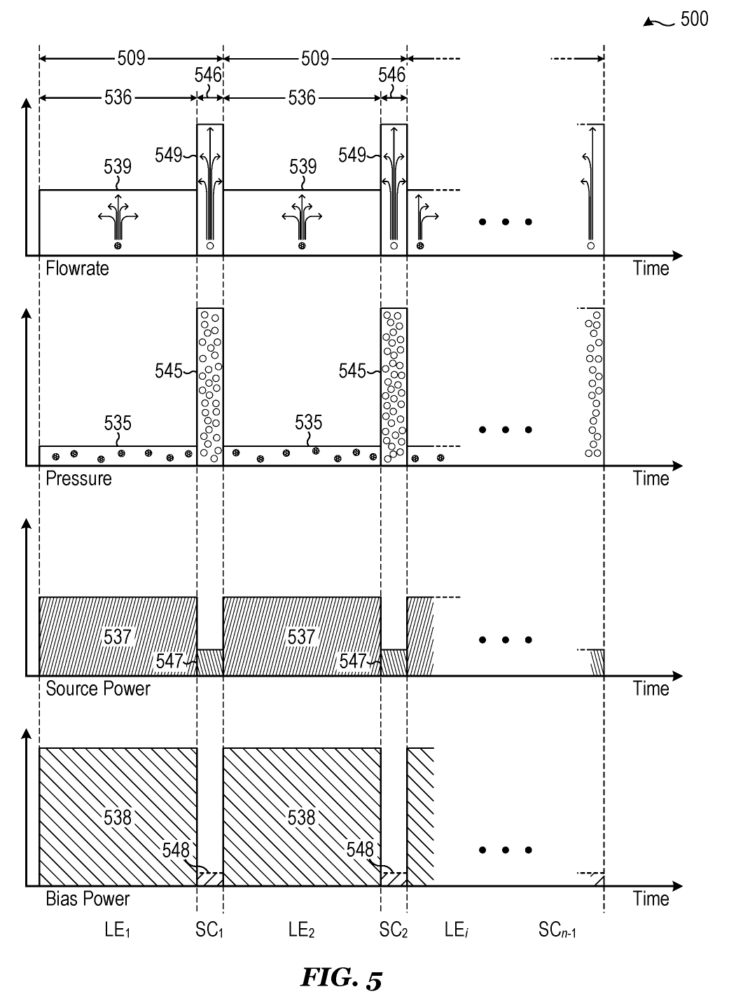

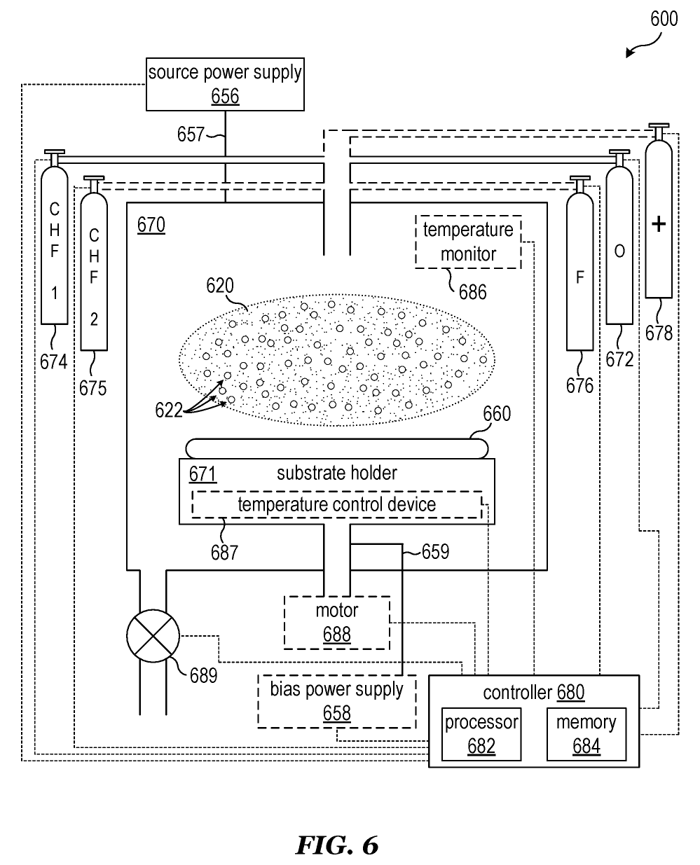

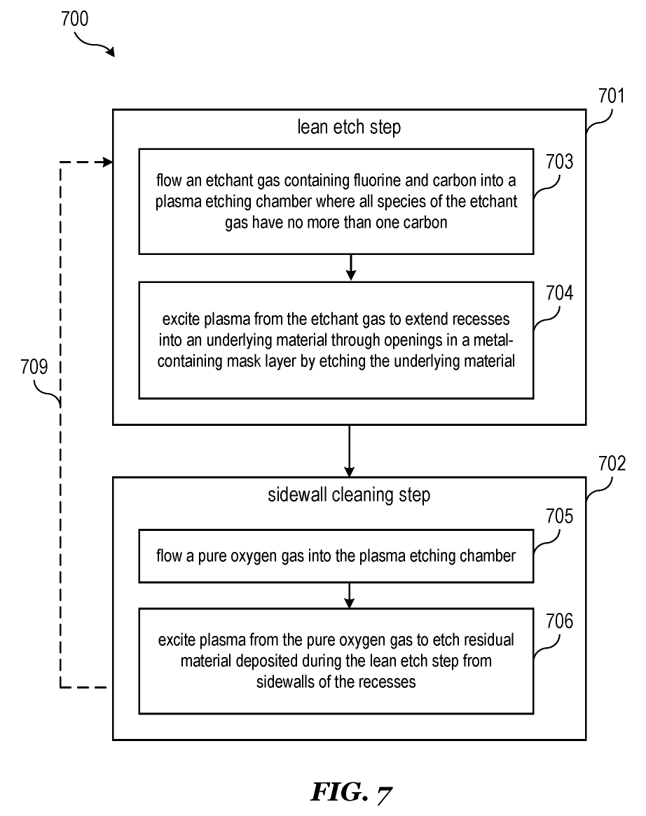

Embodiments provided below describe various systems and methods for plasma etching an underlying material through a metal-containing mask, and in particular embodiments, to system and methods for plasma etching using a two-step process that includes a lean etch step followed by a sidewall cleaning step. The following description describes the embodiments. FIG. 1 is used to describe an example etching process that includes a lean etch step and a sidewall cleaning step. FIG. 2 is used to describe an example etching process where two cycles of the process are shown. Two more example etching processes with specific examples of etchant gas compositions are described using FIGS. 3 and 4. A timing diagram showing various process parameters during an example etching process is described using FIG. 5. FIG. 6 is used to describe an example plasma etching system while FIG. 7 is used to describe an example method of plasma etching.

FIG. 1 schematically illustrates an example etching process that includes a lean etch step followed by a sidewall cleaning step where the lean etch step etches an underlying material through a metal-containing mask and the sidewall cleaning step etches residual material deposited during the lean etch step from feature sidewalls using plasma excited from a pure oxygen gas in accordance with embodiments of the invention.

Referring to FIG. 1, a plasma etching process 100 is shown that includes a lean etch step 101 and a sidewall cleaning step 102. The lean etch step 101 and the sidewall cleaning step 102 may be repeated as part of a cycle 109, in some implementations. The plasma etching process 100 is a HAR etching process in some embodiments and is a HARC etch in one embodiment. The plasma etching process 100 is performed on a substrate 160 that has an underlying material 162 (e.g., a dielectric material, such as an oxide, a nitride, or alternating layers thereof, such as an ONON layer, etc.) exposed through openings 167 in a metal-containing mask layer 166 (e.g., including a metallic component, such as a metal or a metalloid, like W, Si, Ti, etc., which here is schematically depicted as “M”).

During the lean etch step 101, an etchant gas 112 is provided (e.g., flowed) into a plasma etching chamber 170, which is schematically indicated by the dashed line above the substrate 160. An etch plasma 110 is excited from the etchant gas 112, such as by coupling source power to the etchant gas 112. The etch plasma 110 is used to etch the underlying material 162 through the openings 167 extending recesses 164 into the underlying material 162, as shown in the upper right portion of FIG. 1. That is, as the lean etch step 101 progresses during a lean etch step duration 136, the underlying material 162 continues to be etched increasing an etch depth 134.

The etchant gas 112 includes at least one etchant species 114, at least a portion of which is excited to form the etch plasma 110. The etchant gas 112 may advantageously be selected to have lean etch chemistry. For example, various species included in the etchant gas 112 may include carbon (i.e., some may have no carbon), but there are no species included in the etchant gas 112 that have more than one carbon atom. In some embodiments, all species of the etchant gas 112 also include an element other than both fluorine and carbon (e.g., hydrogen, nitrogen, oxygen, etc., in addition to any fluorine and carbon included in the species).

The species of the etchant gas 112 that are considered etchant species may have specific composition characteristics distinguishing them from other species included in the etchant gas 112. For example, all of the etchant species 114 include fluorine (e.g., fluoro- compounds of various types, tetrafluoromethane (CF₄), hydrofluorocarbons CHₓF₄₋ₓ, etc.). In various embodiments, the etchant species 114 include one or more hydrofluorocarbons, and include only hydrofluorocarbons in some embodiments. In one embodiment, the etchant species 114 includes at least one hydrofluorocarbon etchant species. Of course, the etchant gas 112 and the etchant species 114 may be a mixture of various species, selected according to the details of a specific application, some specific examples of which are subsequently discussed.

During the lean etch step 101, residual material 163 (i.e., material buildup, which may be polymer material, such as fluorocarbon polymer, hydrofluorocarbon polymer, etc.) accumulates (e.g., builds up, grows, deposits) on surfaces of the substrate 160. Specifically, the residual material 163 accumulates as sidewall buildup 131 on sidewalls 165 of the recesses 164 and may also accumulate to varying degrees as mask buildup 130 on upper and sidewall surfaces of the metal-containing mask layer 166. Additionally, although typically selected to have high etch resistance to the etchant species 114, the metal-containing mask layer 166 may incur a small amount of mask etch loss 133 (relative to the etch depth 134 which is configured to be much larger, allowing the metal-containing mask layer 166 to be thin).

The metal-containing mask layer 166 may have an initial mask height 132 that is thin relative to some other mask materials, such as carbon-containing mask materials (e.g., ACL masks). For example, the initial mask height 132 may be on the order of a hundred to a few hundred nanometers in various embodiments. In one embodiment, the initial mask height 132 is less than 150 nm, and is about 90 nm in one embodiment. In contrast, an ACL mask may be several microns thick for the same aspect ratio etch, demonstrating the lower etch selectivity compared the metal-containing mask layer 166.

The lean etch step 101 may be continued until reaching an etching end point (or an etching intermediate point if the plasma etching process 100 is performed as the cycle 109) in the plasma etching process 100, such as a certain extension of the etch depth 134 or accumulation of the residual material 163 (the sidewall buildup 131 and/or the mask buildup 130) at which the lean etch step duration 136 ends.

After the lean etch step 101, a pure oxygen gas 122 (e.g., including O₂ gas, O₃ gas, O^{*} radicals, such as from remote oxygen plasma source, etc.) is provided (e.g., flowed) into the plasma etching chamber 170 during the sidewall cleaning step 102. A cleaning plasma 120 is excited from the pure oxygen gas 122, such as by coupling the source power to the pure oxygen gas 122. The source power parameters used to excite the pure oxygen gas 122 may be the same or different than those of the lean etch step 101, which will be subsequently discussed in more detail. The cleaning plasma 120 is used to remove (i.e., etch away through interactions forming volatile species), the residual material 163 from the sidewalls 165 of the recesses 164.

In the earlier period of a sidewall cleaning step duration 146, the cleaning plasma 120 begins to remove the residual material 163 from both the metal-containing mask layer 166 and the underlying material 162 (specifically at least the sidewalls 165, but of course the cleaning plasma 120 may also remove the residual material 163, if any, that is at the bottom of the recesses 164 as well). The pure oxygen gas 122 may be selected so that the cleaning plasma 120 is effective at removing the residual material 163 (e.g., polymer material, such as fluorocarbon polymer, hydrofluorocarbon polymer, etc.) while minimally impacting the metal-containing mask layer 166 and the underlying material 162.

The sidewall cleaning step 102 results in cleaned sidewalls 145 of the recesses 164. The sidewall cleaning step 102 may be continued until reaching a cleaning end point, which may be influenced by the particular details of a given application. For example, it should be noted that although the cleaned sidewalls 145 are shown as being completely devoid of the residual material 163, some of the residual material 163 may remain after the sidewall cleaning step 102. That is, the sidewall cleaning step duration 146 may be optimized to result in an optimal reduction in the sidewall buildup 131, which may include substantially completely cleaning the sidewalls 165, as shown, or may leave a layer of the residual material 163 (e.g., as a passivation layer) which may be more akin to the intermediate depiction of the sidewall cleaning step 102 shown at the bottom left. Additionally, some degree of lateral etching of the underlying material 162 may occur (e.g., bowing), which may be brought closer to the ideal vertical profile by the residual material 163 remaining after the sidewall cleaning step 102.

At some point during the sidewall cleaning step duration 146 (depicted at the bottom right of FIG. 1), surfaces of the metal-containing mask layer 166 may be exposed. In some cases this may result in a mask cleaning loss 143, which can impact etch selectivity of the plasma etching process 100 (but within reasonable ranges to allow the benefits of the sidewall cleaning step 102 to be achieved with little or no modification to the initial mask height 132, for example).

Oxygen reactions with the metallic material M of the metal-containing mask layer 166 may be one mechanism leading to the mask cleaning loss 143. For example, an oxide buildup 140 (e.g., containing metal oxides) may form during the sidewall cleaning step 102. The oxide buildup 140 may be susceptible to etching by the etch plasma 110 (or at least more susceptible than the metal-containing mask layer 166). When the plasma etching process 100 is performed as the cycle 109, a subsequent iteration of the lean etch step 101 may then etch away the oxide buildup 140 resulting in the mask cleaning loss 143. Of course, this but one possible explanation and may not apply to all configurations or applications. For example, the mask cleaning loss 143 may or may not occur, and the exact mechanism may be different for different implementations of the plasma etching process 100.

FIG. 2 schematically illustrates an example etching process that includes a lean etch step followed by a sidewall cleaning step where two cycles of the etching process are shown in accordance with embodiments of the invention. The etching process of FIG. 2 may be a specific implementation of other etching processes described herein such as the etching process of FIG. 1, for example. Similarly labeled elements may be as previously described.

Referring to FIG. 2, a plasma etching process 200 (e.g., a HAR etching process, such as a HARC etch) is shown that includes a lean etch step 201 and a sidewall cleaning step 202. It should be noted that here and in the following a convention has been adopted for brevity and clarity wherein elements adhering to the pattern [x01] where ‘x’ is the figure number may be related implementations of a lean etch step in various embodiments. For example, the lean etch step 201 may be similar to the lean etch step 101 except as otherwise stated. An analogous convention has also been adopted for other elements as made clear by the use of similar terms in conjunction with the aforementioned numbering system.

In this specific example, the lean etch step 201 and the sidewall cleaning step 202 are repeated as part of a cycle 209. The plasma etching process 200 is performed on a substrate 260 that has an underlying material 262 (e.g., a dielectric material, such as an oxide, a nitride, ONON layer, etc.) exposed through openings 267 in a metal-containing mask layer 266 (e.g., including a metallic component, such as a metal or a metalloid, like W, Si, Ti, etc.).

During an iteration of the lean etch step 201, an etchant gas 212 including at least one etchant species 214 is provided (e.g., flowed) into a plasma etching chamber 270 and an etch plasma 210 is excited from the etchant gas 212. The far left segment of FIG. 2 represents the substrate 260 after an etching step has been performed (e.g., a combination of a previous iteration of the lean etch step 201 and the sidewall cleaning step 202). The etch plasma 210 is then used to etch the underlying material 262 through the openings 267 extending recesses 264 into the underlying material 262 and accumulating residual material 263 as sidewall buildup 231 and mask buildup 230.

As shown in the middle segment of FIG. 2, a pure oxygen gas 222 (e.g., including O₂ gas, O₃ gas, O^{*} radicals, such as from remote oxygen plasma source, etc.) is then provided (e.g., flowed) into the plasma etching chamber 270 in an iteration of the sidewall cleaning step 202. A cleaning plasma 220 is excited from the pure oxygen gas 222 and is used to remove the residual material 263 (e.g., polymer material, such as fluorocarbon polymer, hydrofluorocarbon polymer, etc.) from sidewalls 265 of the recesses 264 resulting in cleaned sidewalls 245. The sidewall cleaning step 202 may result in a mask cleaning loss 243 to the metal-containing mask layer 266 (e.g., resulting from oxide buildup 240 that is later etched by a further iteration of the lean etch step 201, or by some other mechanism).

The lean etch step 201 and the sidewall cleaning step 202 may be repeated as desired to achieve the desired etch depth. For example, FIG. 2 shows another iteration of both the lean etch step 201 and the sidewall cleaning step 202 in the fourth and fifth segments where the recesses 264 are further extended into the underlying material 262 with minimal loss of mask material. While some selectivity of the plasma etching process 200 may be lost and the mask facet may be made more aggressive by including iterations of the sidewall cleaning step 202, the benefits reducing distortion in the etch profile while maintaining a desirably high etch rate over the course of the plasma etching process 200 may advantageously outweigh the detriments.

FIG. 3 schematically illustrates an example etching process that includes a lean etch step followed by a sidewall cleaning step, where the etchant gas is a mixture of etchant species in accordance with embodiments of the invention. The etching process of FIG. 3 may be a specific implementation of other etching processes described herein such as the etching process of FIG. 1, for example. Similarly labeled elements may be as previously described.

Referring to FIG. 3, a plasma etching process 300 (e.g., a HAR etching process, such as a HARC etch) is shown that includes a lean etch step 301 and a sidewall cleaning step 302. The lean etch step 301 and the sidewall cleaning step 302 may be repeated as part of a cycle 309, in some implementations. The plasma etching process 300 is performed on a substrate 360 that has an underlying material 362 (e.g., a dielectric material, such as an oxide, a nitride, ONON layer, etc.) exposed through openings 367 in a metal-containing mask layer 366 (e.g., that includes a metallic component, such as a metal or a metalloid, like W, Si, Ti, etc.) with an initial mask height 332.

During the lean etch step 301, an etchant gas 312 is provided (e.g., flowed) into a plasma etching chamber 370. An etch plasma 310 is excited from the etchant gas 312 that is used to etch the underlying material 362 through the openings 367 to extend recesses 364 into the underlying material 362 with little or no mask etch loss 333. The lean etch step 301 may be continued for a lean etch step duration 336 until a desired etch depth 334 or residual material 363 accumulation (as mask buildup 330 and/or sidewall buildup 331 on sidewalls 365 of the recesses 364) is attained.

In this specific example, the etchant gas 312 is a mixture of species that at least includes a first etchant species 314 and a second etchant species 315. The first etchant species 314 and the second etchant species 315 may be any etch species as previous discussed with reference to FIG. 1. Here, the first etchant species 314 is trifluoromethane CHF₃ and the second etchant species 315 is difluoromethane CH₂F₂.

The first etchant species 314 and the second etchant species 315 may be combined in any desired ratio and optionally with additional species to form the etchant gas 312. In various embodiments, the first etchant species 314 and the second etchant species 315 are both at least about 25% of the etchant gas 312, and the ratio of the first etchant species 314 to the second etchant species 315 is about 2:1 in some embodiments, with a ratio of CHF₃:CH₂F₂ being about 2:1 in a specific example.

After the lean etch step 301, a pure O₂ gas 322 (a specific example of a pure oxygen gas where substantially all of the oxygen is provided from a single species: O₂) is provided (e.g., flowed) into the plasma etching chamber 370 for a sidewall cleaning step duration 346 during the sidewall cleaning step 302. A cleaning plasma 320 is excited from the pure O₂ gas 322 and is used to remove (i.e., etch away through interactions forming volatile species), the residual material 363 from the sidewalls 365 of the recesses 364 resulting in cleaned sidewalls 345. The sidewall cleaning step 302 may result in a mask cleaning loss 343 to the metal-containing mask layer 366 (e.g., resulting from oxide buildup 340 that is later etched by a further iteration of the lean etch step 301, or by some other mechanism).

FIG. 4 schematically illustrates an example etching process that includes a lean etch step followed by a sidewall cleaning step, where the etchant gas has two carbon-containing etchant species, a carbon-free fluorine-containing species, and a balancing species in accordance with embodiments of the invention. The etching process of FIG. 4 may be a specific implementation of other etching processes described herein such as the etching process of FIG. 1, for example. Similarly labeled elements may be as previously described.

Referring to FIG. 4, a plasma etching process 400 (e.g., a HAR etching process, such as a HARC etch) is shown that includes a lean etch step 401 and a sidewall cleaning step 402. The lean etch step 401 and the sidewall cleaning step 402 may be repeated as part of a cycle 409, in some implementations. The plasma etching process 400 is performed on a substrate 460 that has an underlying material 462 (e.g., a dielectric material, such as an oxide, a nitride, ONON layer, etc.) exposed through openings 467 in a metal-containing mask layer 466 with an initial mask height 432. In this specific example, the metal-containing mask layer 466 is a WSiₓ (tungsten silicide) mask layer, having some ratio of W to Si, such as a W:Si ratio of 60:40.

During the lean etch step 401, an etchant gas 412 is provided (e.g., flowed) into a plasma etching chamber 470. An etch plasma 410 is excited from the etchant gas 412 that is used to etch the underlying material 462 through the openings 467 to extend recesses 464 into the underlying material 462 with little or no mask etch loss 433. The lean etch step 401 may be continued for a lean etch step duration 436 until a desired etch depth 434 or residual material 463 accumulation (as mask buildup 430 and/or sidewall buildup 431 on sidewalls 465 of the recesses 464) is attained.

In this specific example, the etchant gas 412 is a mixture of species that includes a first etchant species 414 (such as CHF₃), a second etchant species 415 (such as CH₂F₂), a carbon-free fluorine-containing species 416, which here is nitrogen trifluoride (NF₃), and a balancing species 418. The carbon-free fluorine-containing species 416 is a free-fluorine source that does not include carbon. Other possible options for the carbon-free fluorine-containing species 416 include hydrogen fluoride (HF) and sulfur hexafluoride (SF₆), among others. In various embodiments, the balancing species 418 is an oxygen-containing species and is a nitrogen-containing species in other embodiments. In some embodiments, the balancing species 418 includes one or more species also included in a pure oxygen gas used in s subsequent cleaning step, which is the case here, with the balancing species 418 being O₂. However, other species, such as may also be used, one example of which is carbon oxysulfide (COS).

The first etchant species 414, the second etchant species 415, the carbon-free fluorine-containing species 416, and the balancing species 418 may be combined in any desired ratio and optionally with additional species to form the etchant gas 412. In various embodiments, the first etchant species 414 and the second etchant species 415 are both at least about 25% of the etchant gas 412, and the ratio of the first etchant species 414 to the second etchant species 415 is about 2:1 in some embodiments, with a ratio of CHF₃:CH₂F₂ being about 2:1 in a specific example.

Similarly, the carbon-free fluorine-containing species 416 makes up at least about 25% of the species of the etchant gas 412 in various embodiments, and the ratio of the first etchant species 414 to the carbon-free fluorine-containing species 416 is about 2:1 in some embodiments, with a ratio of CHF₃:CH₂F₂ being about 2:1 in a specific example. The relative concentration of the balancing species 418 may be lower than the other species of the etchant gas 412, such as less than about 5% of the etchant gas 412. For example, the ratio of the first etchant species 414 to the balancing species 418 may be about 50:3 in one embodiment.

The ratio of gases in the etchant gas 412 may also be described in terms of the ratio of various constituent elements, such as the fluorine-to-carbon (F:C) and the oxygen-carbon ratio (O:C). The F:C ratio may be higher (e.g., much higher) than the O:C ratio. In one embodiment, the F:C ratio is greater than about 3:1. In one embodiment, the F:C ratio is less than about 1:25. Of course the specific ratios (both inter-species and inter-element) may depend on the specific details of a given application.

After the lean etch step 401, a pure O₂ gas 422 is provided (e.g., flowed) into the plasma etching chamber 470 for a sidewall cleaning step duration 446 during the sidewall cleaning step 402. A cleaning plasma 420 is excited from the pure O₂ gas 422 and is used to remove (i.e., etch away through interactions forming volatile species), the residual material 463 from the sidewalls 465 of the recesses 464 resulting in cleaned sidewalls 445. The sidewall cleaning step 402 may result in a mask cleaning loss 443 to the metal-containing mask layer 466 (e.g., resulting from oxide buildup 440 that is later etched by a further iteration of the lean etch step 401, or by some other mechanism). For example, in this specific example, tungsten oxide bonds (W–O) and silicon oxide bonds (Si–O) may be formed.

FIG. 5 illustrates a timing diagram qualitatively showing flowrates of an etchant gas and a pure oxygen gas, chamber pressure, source power, and bias power during both a lean etch step and a sidewall cleaning step of an example etching process in accordance with embodiments of the invention. The timing diagram of FIG. 5 may correspond to any of the etching processes described herein, such as the etching processes of FIGS. 1–4, for example.

Referring to FIG. 5, a plasma etching process 500 (e.g., a HAR etching process, such as a HARC etch) is shown where a cycle 509 including alternating lean etch steps (LEi) and sidewall cleaning steps (SCi) is repeated. Each cycle 509 includes a lean etch step duration 536 and a cleaning step duration 546 (although the plasma etching process 500 may end on a lean etch step since an ashing step may following the plasma etching process 500). The relative magnitudes of several example process parameters are qualitatively illustrated for the plasma etching process 500. For example, the flowrate, pressure, source power, and bias power are shown, but of course many other process parameters may be used and may depend the details of a given application).

During the lean etch steps, the total etchant gas flowrate 539 may be lower than the total cleaning gas flowrate 549 during the sidewall cleaning steps. As already discussed, the etchant gas may include various species which all may be provided at individual flowrates that add up to the total etchant gas flowrate 539 and define the ratios of the various species in the etchant gas. This also applies to the pure oxygen gas, although the universe of species that may be included in the pure oxygen gas are fewer. In various embodiments, the total etchant gas flowrate 539 is less than about 75% of the total cleaning gas flowrate 549, and is less than about 50% in some embodiments. In one embodiment, the total etchant gas flowrate 539 is about 50% of the total cleaning gas flowrate 549.

Similarly, although the chamber pressure may be controlled separately at least to some extent using knobs such as the degree that the exhaust valve is open, the etch pressure 535 during the lean steps may be lower than the cleaning pressure 545 during the sidewall cleaning steps. As shown in the example, the disparity between the etch pressure 535 and the cleaning pressure 545 may be different than that of the flowrate values. In various embodiments, the etch pressure 535 is less than about 25% of the cleaning pressure 545 is less than about 15% of the cleaning pressure 545 in one embodiment.

In contrast to the flowrate and pressure, the etch source power 537 and the etch bias power 538 during the lean etch steps may be higher than the cleaning source power 547 and the sidewall cleaning bias power 548 during the sidewall cleaning steps. Notably, the etch source power 537 may also be lower that source power used in conventional etching methods, which may be enabled by the lean etch chemistry. In various embodiments, the etch source power 537 is greater than about 200% of the cleaning source power 547, and is greater than about 150% of the cleaning source power 547 in one embodiment.

The relative magnitudes of the etch bias power 538 and the sidewall cleaning bias power 548 may be even higher. Additionally, the sidewall cleaning bias power 548 may be advantageously omitted entirely. In various embodiments, the etch bias power 538 is greater than about 400% of the sidewall cleaning bias power 548, and is greater than about 800% of the sidewall cleaning bias power 548 in some embodiments. In one embodiment, the sidewall cleaning bias power 548 is zero during the sidewall cleaning steps.

The relative magnitudes of the lean etch step duration 536 and the sidewall cleaning step duration 546 may also be tuned to achieve the desired results for a given application. For example, the sidewall cleaning step duration 546 may be advantageously made small relative to the lean etch step duration 536 (e.g., because residual material, such as polymer, accumulates relatively slowly due to the lean etch chemistry). For example, the lean etch step duration 536 may be greater than about 400% of the sidewall cleaning step duration 546 in various embodiments. In terms of units, the lean etch step duration 536 may be on the order of 60 s while the sidewall cleaning step duration 546 may be on the order of single digits of seconds. In one embodiment, the sidewall cleaning step duration 546 is about 10 s while the lean etch step duration 536 is about 60 s, but even in this embodiment the actual values used may vary around these numbers based on process optimization.

Another potential advantage of the plasma etching processes described herein may be that the sidewall cleaning step duration 546 can be made longer if needed (e.g., since the mask layer has more resistance to oxygen plasma than carbon-containing mask materials, for example). This may be advantageous for reaching sidewalls at or near the bottoms of features, to more fully remove residual material, or for other reasons. Additionally, since very little of the mask is lost by incorporating even multiple sidewall cleaning steps, the total number of sidewall etching steps and the total duration of the oxygen plasma exposure may be advantageously high (e.g., much higher than would be possible with a carbon-containing mask).

FIG. 6 schematically illustrates an example plasma etching system usable to perform etching processes that include a lean etch step followed by a sidewall cleaning step in accordance with embodiments of the invention. The plasma etching system of FIG. 6 may be used to perform any of the methods and processes described herein, such as the etching processes of FIGS. 1–4, the timing diagram of FIG. 5, and the method of FIG. 7, for example. Similarly labeled elements may be as previously described.

Referring to FIG. 6, a plasma etching system 600 (e.g., a reactive-ion etching (RIE) etching system) includes a plasma etching chamber 670 configured to contain a substrate 660. A substrate holder 671 is disposed within the plasma etching chamber 670 and configured to support the substrate 660. An oxygen source 672 (e.g., a gas source that includes oxygen) is fluidically coupled to the plasma etching chamber 670 and configured to supply a pure oxygen gas 622 into the plasma etching chamber 670. A first etchant source 674 (e.g., a gas source that includes an etchant species with fluorine and carbon, such as a hydrofluorocarbon etchant species) is also fluidically coupled to the plasma etching chamber 670.

An optional second etchant source 675 (or more than one additional etchant source) may be included to supply additional etchant species. An optional free-fluorine source 676 may be included to supply a carbon-free fluorine-containing species (e.g., a species containing fluorine, but not carbon). An optional additional gas source 678 may also be included to supply other gases as needed, such as carrier gases, additional reactants, or others.

The plasma etching system 600 is configured to generate plasma during the plasma etching processes. Specifically, a source power supply 656 is configured to couple source power 657 to the plasma etching chamber 670 in order to excite plasma from gases within the chamber (i.e., at least cleaning plasma 620 and an etch plasma, as well as other plasmas, if desired). A bias power supply 658 is also included and configured to supply bias power 659 to the substrate holder 671 (and the substrate 660), such as to accelerate ions in the plasma towards the substrate 660.

An exhaust valve 689 may be included to control evacuation of the plasma etching chamber 670 during the plasma etching processes. An optional temperature monitor 686 may be included to monitor and/or aid in controlling the temperature of the substrate 660 and the environment in the plasma etching chamber 670. An optional temperature control device 687 may be included to raise or lower the temperature of the substrate 660 above or below the equilibrium temperature during the plasma etching processes. An optional motor 688 may also be included to improve process uniformity.

A controller 680 is operatively coupled to the various components of the plasma etching system 600, including the gas sources, power supplies, and valves. The controller 680 includes a processor 682 and a memory 684 (i.e., a non-transitory computer-readable medium) that stores a program including instructions that, when executed by the processor 682, perform the plasma etching processes described herein. For example, the memory 684 may have volatile memory (e.g., random access memory (RAM)) and non-volatile memory (e.g., flash memory). Alternatively, the program may be stored in physical memory at a remote location, such as in cloud storage. The processor 682 may be any suitable processor, such as the processor of a microcontroller, a general-purpose processor (such as a central processing unit (CPU), a microprocessor, a field-programmable gate array (FPGA), an application-specific integrated circuit (ASIC), and others.

The plasma etching system 600 is configured to perform plasma etching processes that include a lean etch step to extend recesses into an underlying material through openings in a metal-containing mask layer, followed by a sidewall cleaning step using plasma excited from the pure oxygen gas 622 to etch residual material deposited during the lean etch step. The plasma etching system 600 is configured to perform various methods that incorporate some or all steps of embodiment plasma etching processes apparent to those of ordinary skill in the art in view of the present disclosure. For example, the plasma etching system 600 is configured to control gas flow rates, chamber pressure, source power levels, and bias power levels during the lean etch and sidewall cleaning steps.

FIG. 7 illustrates a flowchart of a method of plasma etching that use etching processes including a lean etch step followed by a sidewall cleaning step in accordance with embodiments of the invention. The method of FIG. 7 may be combined with other methods and performed using the systems and apparatuses as described herein. For example, the method of FIG. 7 may be combined with any of the embodiments of FIGS. 1–6.

Referring to FIG. 7, Referring to FIG. 7, the method 700 of plasma etching includes performing a lean etch step 701 and a sidewall cleaning step 702. The lean etch step 701 includes a step 703 of flowing an etchant gas into a plasma etching chamber. The etchant gas contains both fluorine and carbon in various species, such as including a hydrofluorocarbon etchant species. In one embodiment, the etchant gas includes at least one hydrofluorocarbon etchant species. All species of the etchant gas include no more than one carbon. In some embodiments, all species of the etchant gas include an element other than fluorine and carbon. The lean etch step 701 further includes a step 704 of exciting plasma from the etchant gas to extend recesses into an underlying material through openings in a metal-containing mask layer by etching the underlying material.

The etchant gas may include various other species which may or may not participate directly in the etching of the underlying material. In various embodiments, the etchant species are a mix of at least two different hydrofluorocarbon species, such as a mixture of trifluoromethane (CHF₃) and difluoromethane (CH₂F₂). In some embodiments, the etchant gas includes a carbon-free fluorine-containing species, which is nitrogen trifluoride (NF₃) in one embodiment. The etchant gas may further include a balancing agent (e.g., containing oxygen), which is diatomic oxygen (O₂) in one embodiment.

During the lean etch step 701, the etchant gas is configured to have lean etch chemistry, such as having a fluorine-to-carbon ratio controlled to be greater than about 3:1 (but can also be lower or higher as desired). Similarly, the oxygen-to-carbon ratio of the etchant gas may be controlled to be less than about 1:25, but of course, other ratios are also possible.

The sidewall cleaning step 702 includes a step 705 of flowing a pure oxygen gas into the plasma etching chamber and exciting plasma from the pure oxygen gas during a step 706 to etch residual material deposited during the lean etch step from sidewalls of the recesses. The pure oxygen gas is pure O₂ gas in one embodiment. The lean etch step 701 and the sidewall cleaning step of the method 700 may be repeated as part of a cycle 709 (e.g., without evacuating the plasma etching chamber between steps).

During the sidewall cleaning step 702, the total gas flowrate may be controlled to be at least double the total gas flowrate during the lean etch step 701. The pressure of the plasma etching chamber during the sidewall cleaning step 702 may be controlled to be at least five times the pressure during the lean etch step 701.

In some embodiments, the metal-containing mask layer is tungsten silicide (WSiₓ). The method 700 may be a high aspect ratio contact (HARC) etch. The underlying material includes a dielectric material in some embodiments, and includes alternating layers of oxide and nitride (ONON) in one embodiment.

The etchant gas may be flowed into the plasma etching chamber using an etchant source, which may be several gas sources (e.g., one or more gases simultaneously flowed form an etchant gas that is a mixture of multiple species). The pure oxygen gas may be flowed into the plasma etching chamber using an oxygen source. In some cases (i.e., when a balancing agent is included in the etchant gas that is the same as the pure oxygen gas), the oxygen source may also be activated to flow the pure oxygen source during the lean etch step 701.

The method 700 may involve providing source power (e.g., using a source power supply) during the lean etch step 701 at a source power level between about 1 kW and about 5 kW, and during the sidewall cleaning step 702 at a source power level between about 500 W and about 2 kW. Bias power (e.g., using a bias power supply) may be provided at the substrate during the lean etch step 701 at a bias power level between about 2.5 kW and about 10 kW, and the bias power may be removed during the sidewall cleaning step 702.

Example embodiments of the invention are summarized here. Other embodiments can also be understood from the entirety of the specification as well as the claims filed herein.

Example 1. A method of plasma etching including cyclically performing the following steps: etching an underlying material to extend recesses into the underlying material through openings in a metal-containing mask layer using plasma excited from an etchant gas including at least one hydrofluorocarbon etchant species, all species of the etchant gas including no more than one carbon and including an element other than fluorine and carbon; and etching residual material from sidewalls of the recesses using plasma excited from a pure oxygen gas, the residual material being deposited while etching the underlying material.

Example 2. The method of example 1, where the pure oxygen gas is pure diatomic oxygen (O₂) gas.

Example 3. The method of example 2, where the at least one hydrofluorocarbon etchant species is a mix of at least two different hydrofluorocarbon species.

Example 4. The method of one of examples 1 to 3, where the etchant gas further includes a carbon-free fluorine-containing species.

Example 5. The method of example 4, where the etchant gas further includes a balancing species including oxygen.

Example 6. A method of HAR etching including cyclically performing the following steps: performing a lean etch step including flowing an etchant gas into a plasma etching chamber, the etchant gas including at least one hydrofluorocarbon etchant species and a carbon-free fluorine-containing species, all species of the etchant gas including no more than one carbon and including an element other than fluorine and carbon, and exciting plasma from the etchant gas to extend recesses into an underlying material through openings in a metal-containing mask layer by etching the underlying material; and performing a sidewall cleaning step including flowing a pure O₂ gas into the plasma etching chamber, and exciting plasma from the pure O₂ gas to etch residual material deposited during the lean etch step from sidewalls of the recesses.

Example 7. The method of example 6, where the at least one hydrofluorocarbon etchant species is a mix of at least two different hydrofluorocarbon species.

Example 8. The method of example 7, where the at least two different hydrofluorocarbon species include CHF₃ (trifluoromethane) and CH₂F₂ (difluoromethane).

Example 9. The method of example 8, where the carbon-free fluorine-containing species is NF₃ (nitrogen trifluoride).

Example 10. The method of example 9, where the etchant gas further includes O₂ (diatomic oxygen).

Example 11. The method of one of examples 6 to 10, where the fluorine-to-carbon ratio of the etchant gas is greater than about 3:1.

Example 12. The method of one of examples 6 to 11, where the etchant gas further includes a balancing species including oxygen.

Example 13. The method of example 12, where the oxygen-to-carbon ratio of the etchant gas is less than about 1:25.

Example 14. The method of one of examples 12 and 13, where the balancing species is O₂ (diatomic oxygen).

Example 15. The method of one of examples 6 to 14, where the metal-containing mask layer is WSiₓ (tungsten silicide).

Example 16. The method of one of examples 6 to 15, where the method is a HARC etch, the underlying material including alternating layers of oxide and nitride (ONON).

Example 17. A plasma etching system including: a plasma etching chamber; a substrate holder disposed in the plasma etching chamber and configured to support a substrate including a metal-containing mask layer including openings exposing an underlying material; an etchant source fluidically coupled to the plasma etching chamber and configured to flow one or more gases including at least one hydrofluorocarbon etchant species into the plasma etching chamber, all species of the one or more gases including no more than one carbon and including an element other than fluorine and carbon; an oxygen source fluidically coupled to the plasma etching chamber and configured to flow a pure oxygen gas into the plasma etching chamber; a source power supply configured to couple source power to gases in the plasma etching chamber to excite plasma therein; and a controller operationally coupled to the etchant source, the oxygen source, and the source power supply, the controller including a processor and a non-transitory computer-readable medium storing a program including instructions that, when executed by the processor, perform a method of plasma etching by cyclically performing a lean etch step including flowing the one or more gases into the plasma etching chamber, and exciting plasma from the one or more gases to extend recesses into the underlying material by etching the underlying material, and performing a sidewall cleaning step including flowing the pure oxygen gas into the plasma etching chamber, and exciting plasma from the pure oxygen gas to etch residual material deposited during the lean etch step from sidewalls of the recesses.

Example 18. The plasma etching system of example 17, where the controller is further configured to cyclically perform the lean etch step and the sidewall cleaning step without evacuating the plasma etching chamber between steps.

Example 19. The plasma etching system of one of examples 17 and 18, where the controller is further configured to control the total gas flowrate during the sidewall cleaning step to be at least double the total gas flowrate during the lean etch step, and control the pressure of the plasma etching chamber during the sidewall cleaning step to be at least five times of the pressure of the plasma etching chamber during the lean etch step.

Example 20. The plasma etching system of one of examples 17 to 19, further including: a bias power supply configured to couple bias power to the substrate, where the controller is further configured to provide the source power during the lean etch step at a source power level between about 1 kW and about 5 kW, provide the source power during the sidewall cleaning step at a source power level between about 500 W and about 2 kW, provide the bias power at the substrate during the lean etch step at a bias power level between about 2.5 kW and about 10 kW, and remove the bias power from the substrate during the sidewall cleaning step.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of plasma etching comprising cyclically performing the following steps:
etching an underlying material to extend recesses into the underlying material through openings in a metal-containing mask layer using plasma excited from an etchant gas comprising at least one hydrofluorocarbon etchant species, all species of the etchant gas comprising no more than one carbon and comprising an element other than fluorine and carbon; and
etching residual material from sidewalls of the recesses using plasma excited from a pure oxygen gas, the residual material being deposited while etching the underlying material.

2. The method of claim 1, wherein the pure oxygen gas is pure diatomic oxygen (O₂) gas.

3. The method of claim 2, wherein the at least one hydrofluorocarbon etchant species is a mix of at least two different hydrofluorocarbon species.

4. The method of claim 1, wherein the etchant gas further comprises a carbon-free fluorine-containing species.

5. The method of claim 4, wherein the etchant gas further comprises a balancing species comprising oxygen.

6. A method of high aspect ratio (HAR) etching comprising cyclically performing the following steps:
performing a lean etch step comprising
flowing an etchant gas into a plasma etching chamber, the etchant gas comprising at least one hydrofluorocarbon etchant species and a carbon-free fluorine-containing species, all species of the etchant gas comprising no more than one carbon and comprising an element other than fluorine and carbon, and
exciting plasma from the etchant gas to extend recesses into an underlying material through openings in a metal-containing mask layer by etching the underlying material; and
performing a sidewall cleaning step comprising
flowing a pure diatomic oxygen (O2) gas into the plasma etching chamber, and
exciting plasma from the pure O2 gas to etch residual material deposited during the lean etch step from sidewalls of the recesses.

7. The method of claim 6, wherein the at least one hydrofluorocarbon etchant species is a mix of at least two different hydrofluorocarbon species.

8. The method of claim 7, wherein the at least two different hydrofluorocarbon species comprise trifluoromethane (CHF₃) and difluoromethane (CH₂F₂).

9. The method of claim 8, wherein the carbon-free fluorine-containing species is nitrogen trifluoride (NF₃).

10. The method of claim 9, wherein the etchant gas further comprises diatomic oxygen (O₂).

11. The method of claim 6, wherein the fluorine-to-carbon ratio of the etchant gas is greater than about 3:1.

12. The method of claim 6, wherein the etchant gas further comprises a balancing species comprising oxygen.

13. The method of claim 12, wherein the oxygen-to-carbon ratio of the etchant gas is less than about 1:25.

14. The method of claim 12, wherein the balancing species is diatomic oxygen (O₂).

15. The method of claim 6, wherein the metal-containing mask layer is tungsten silicide (WSiₓ).

16. The method of claim 6, wherein the method is a high aspect ratio contact (HARC) etch, the underlying material comprising alternating layers of oxide and nitride (ONON).

17. A plasma etching system comprising:
a plasma etching chamber;
a substrate holder disposed in the plasma etching chamber and configured to support a substrate comprising a metal-containing mask layer comprising openings exposing an underlying material;
an etchant source fluidically coupled to the plasma etching chamber and configured to flow one or more gases comprising at least one hydrofluorocarbon etchant species into the plasma etching chamber, all species of the one or more gases comprising no more than one carbon and comprising an element other than fluorine and carbon;
an oxygen source fluidically coupled to the plasma etching chamber and configured to flow a pure oxygen gas into the plasma etching chamber;
a source power supply configured to couple source power to gases in the plasma etching chamber to excite plasma therein; and
a controller operationally coupled to the etchant source, the oxygen source, and the source power supply, the controller comprising a processor and a non-transitory computer-readable medium storing a program including instructions that, when executed by the processor, perform a method of plasma etching by cyclically
performing a lean etch step comprising flowing the one or more gases into the plasma etching chamber, and exciting plasma from the one or more gases to extend recesses into the underlying material by etching the underlying material, and
performing a sidewall cleaning step comprising flowing the pure oxygen gas into the plasma etching chamber, and exciting plasma from the pure oxygen gas to etch residual material deposited during the lean etch step from sidewalls of the recesses.

18. The plasma etching system of claim 17, wherein the controller is further configured to cyclically perform the lean etch step and the sidewall cleaning step without evacuating the plasma etching chamber between steps.

19. The plasma etching system of claim 17, wherein the controller is further configured to
control the total gas flowrate during the sidewall cleaning step to be at least double the total gas flowrate during the lean etch step, and
control the pressure of the plasma etching chamber during the sidewall cleaning step to be at least five times of the pressure of the plasma etching chamber during the lean etch step.

20. The plasma etching system of claim 17, further comprising:
a bias power supply configured to couple bias power to the substrate,
wherein the controller is further configured to
provide the source power during the lean etch step at a source power level between about 1 kW and about 5 kW,
provide the source power during the sidewall cleaning step at a source power level between about 500 W and about 2 kW,
provide the bias power at the substrate during the lean etch step at a bias power level between about 2.5 kW and about 10 kW, and
remove the bias power from the substrate during the sidewall cleaning step.
